(19) United States
(12) Patent Application Publication
(10) Pub. No.: US 2026/0196710 A1
(43) Pub. Date: Jul. 9, 2026

(54) CIRCUIT ASSEMBLY AND DEVICE WITH RADIO FREQUENCY CONTACTS

(71) Applicant: NXP B.V., Eindhoven (NL)

(72) Inventors: Manuel Alfredo Monedero Miranda, Munich (DE); Vishwadeep Nikhil Sharma Suryanarayana, Munich (DE); Naga Kota Paidi Venkatesh Budde, Munich (DE)

(21) Appl. No.: 19/426,418

(22) Filed: Dec. 19, 2025

(30) Foreign Application Priority Data
Jan. 6, 2025 (EP) 25150342.1

(51) Int. Cl. H01Q 1/22; H01Q 1/52; H01Q 13/00

(52) U.S. Cl. CPC H01Q 1/2283; H01Q 1/526; H01Q 13/00

(57) ABSTRACT

A circuit assembly includes a packaged electronic device having an RF (radio frequency) contact and a shield contact. The circuit assembly further includes a substrate coupled to the packaged electronic device and at least partially containing an inner conductive structure electrically coupled to the RF contact and an outer conductive structure electrically coupled to the shield contact, the inner conductive structure and the outer conductive structure forming a vertical coaxial structure through the substrate. The circuit assembly still further includes a waveguide antenna electrically coupled to the coaxial structure on a side of the substrate opposite the packaged electronic device. Further embodiments are directed to a device suitable for use in a circuit assembly as described above.

### CROSS-REFERENCE TO RELATED APPLICATIONS

This application claims priority under 35 U.S.C. § 119 to European patent application no. 25150342.1, filed 6 Jan. 2025, the contents of which are incorporated by reference herein.

### BACKGROUND

RF (radio frequency) integrated circuits (“chips”) are commonly made in packages that convey RF signals between the chips and external components. One type of package for an RF chip is a modified ball grid array (BGA). The modified BGA has a surface on which an array of solder balls (also called solder “bumps”) is disposed. The solder balls connect with electrical nodes inside the chip and bond with conductive pads on a circuit board when the package is soldered to the circuit board.

The modified BGA includes a conductive patch disposed among the solder balls, along an area of the same surface on which the array of solder balls is disposed. The conductive patch is electrically coupled to an RF source inside the chip. When the package is soldered to a circuit board, the conductive patch vertically aligns with a rectangular conductive slot formed in the circuit board. The conductive slot acts as a waveguide to convey signals emitted by the conductive patch to an antenna beneath the circuit board.

A typical BGA for an RF chip may include multiple conductive patches for transmitting multiple RF signals. In a common arrangement, the RF chip may be realized as an mmWave (millimeter wave) monolithic microwave integrated circuit (MMIC) and the above-described arrangement for conveying RF signals may be referred to as a launcher-in-package (LiP).

### BRIEF DESCRIPTION OF THE SEVERAL VIEWS OF THE DRAWINGS

The foregoing and other features and advantages will be apparent from the following description of particular embodiments, as illustrated in the accompanying drawings, in which like reference characters refer to the same or similar parts throughout the different views. The drawings are not necessarily to scale, emphasis instead being placed upon illustrating the principles of various embodiments.

FIG. 1 is a front, cross-sectional view of a first circuit assembly according to one or more embodiments.

FIG. 2 is a bottom plan view of an example integrated circuit package of FIG. 1 according to one or more embodiments.

FIG. 3 is a top plan view of an example substrate of FIG. 1 according to one or more embodiments.

FIG. 4 is a bottom plan view of the example substrate of FIGS. 1 and 3 according to one or more embodiments.

FIG. 5 is a front, cross-sectional view of a second circuit assembly according to one or more embodiments.

FIG. 6 is a front, cross-sectional view of a third circuit assembly according to one or more embodiments.

FIG. 7 is a bottom plan view of the example substrate of FIG. 6 according to one or more embodiments.

FIG. 8 is a partly transparent, top-left isometric view of the first circuit assembly according to one or more embodiments.

FIG. 9 is a front elevation view of the example device of FIG. 1 according to one or more embodiments.

### DETAILED DESCRIPTION

The above-described launcher-in-package (LiP) for conveying RF signals between a chip and an antenna delivers low insertion loss and high return loss at microwave frequencies, making LiP technology a good fit for demanding applications, such as radar (radio detection and ranging). However, the high performance of LiP technology comes at the cost of space, as the required conductive patch tends to be much larger than a typical integrated circuit contact. For example, one conductive patch can extend over the same area as would be occupied by ten or more solder balls of a BGA, even without counting the ground shielding normally needed around the conductive patch. The size of the conductive patch is carefully optimized for coupling with the waveguide antenna and cannot easily be changed. LiP solutions thus tend to drive up the sizes of RF device packages, consuming valuable space on circuit boards and resisting reductions in size that normally accompany improvements in other components. What is needed, therefore, is a way of conveying RF signals using less space than is required by LiP solutions, without significantly impacting performance.

The above need is addressed at least in part by an improved technique of conveying RF signals between a packaged electronic device and a waveguide antenna. The packaged electronic device contains an integrated circuit configured to transmit and/or receive RF signals. The device is attached (e.g., soldered) to a first side of a substrate, such as a printed circuit board, ceramic substrate, or flex board, and the waveguide antenna is attached (e.g., soldered, screwed, or otherwise fastened) to a second side of the substrate opposite the first side. The device includes an RF contact and an adjacent shield contact. Inside a package of the device, the RF contact and the shield contact are electrically coupled to RF circuitry of the integrated circuit. Outside the package of the device, the RF contact is electrically coupled to the waveguide antenna along an inner conductive structure that extends vertically through the substrate, and the shield contact is electrically coupled to the waveguide antenna along an outer conductive structure that at least partially surrounds the inner conductive structure. The inner conductive structure and the outer conductive structure form a coaxial vertical structure that provides a controlled impedance path through the substrate, enabling RF signals to propagate between the device and the waveguide antenna without significant losses or reflections.

Advantageously, the improved technique consumes less space than does the LiP solution. The improved technique also provides comparable results to the LiP solution in terms of insertion loss, thus enabling further miniaturization of RF and microwave components while achieving similar performance.

According to one or more embodiments, the packaged device includes an RF pin electrically and mechanically connected to the RF contact. The RF pin extends through a vertical hole in the substrate and to the antenna, providing the inner conductor of the coaxial structure. The vertical hole is a plated hole that is electrically coupled to the shield contact, which may be provided, for example, as a conventional solder ball of a ball grid array (BGA) or a conventional land of a land grid array (LGA). The RF pin thus forms a center conductor of the coaxial structure, and the plated hole forms a shield of the coaxial structure spaced apart from the RF pin.

According to one or more further embodiments, the RF contact includes a contact pad, which may be flat or substantially flat. For example, the contact pad may be the same type of pad (e.g., same size, shape, and material) as that which is provided for attaching to solder balls of a BGA or for providing lands of an LGA. The substrate has a vertical plated hole aligned with the RF contact and electrically coupled to the shield contact. In these embodiments, the antenna includes a pin, which extends up through the plated hole in the substrate and abuts the RF contact. The coaxial structure is thus formed by the upward-extending pin as the center conductor and the plated hole as the shield.

According to one or more still further embodiments, the RF contact is provided as a conventional contact, such as a solder ball of a BGA or land of an LGA. The substrate includes a central via electrically connected to the RF contact. The substrate further includes multiple shield vias that laterally surround the central via. The shield vias are electrically coupled to the shield contact of the packaged device. The inner via and the shield vias together form the vertical coaxial structure. The waveguide antenna is electrically coupled to the coaxial structure on the second side of the substrate.

Embodiments of the improved technique will now be described. One should appreciate that such embodiments are provided by way of example to illustrate certain features and principles but are not intended to be limiting.

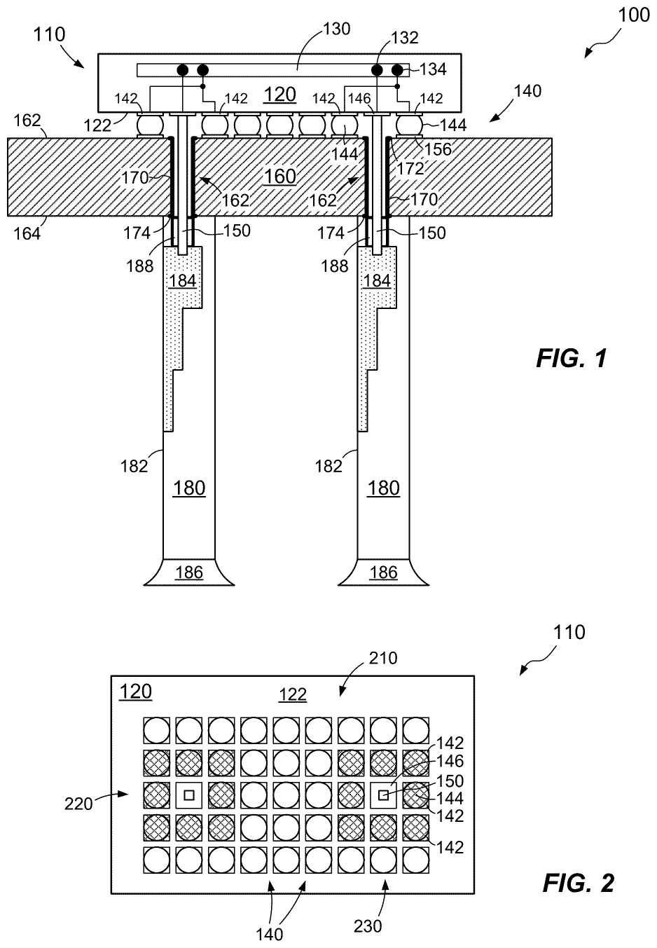

FIG. 1 is a front, cross-sectional view of an example circuit assembly 100 according to one or more embodiments. The circuit assembly 100 includes a packaged electronic device 110, a substrate 160, and one or more waveguide antennas 180.

The packaged electronic device (“device”) 110 includes a package 120, one or more integrated circuits (chips) 130 within the package 120 (a single chip is shown), and various terminals. The terminals are formed at or on a bottom surface 122 of the package 120 and provide electrical contacts for conveying signals, power, and ground into and out of the device 110. In the depicted example, the device 110 is a ball grid array (BGA). Other arrangements are also feasible, though, such as land grid arrays (LGAs).

The terminals include both standard terminals 140 and RF pins 150. The standard terminals 140 include multiple contact pads 142 fused with respective solder balls 144 (also called solder “bumps”’ assuming a BGA example). The contact pads 142 may be connected to electrical nodes of the chip (or chips) 130 inside the package 120.

Each of the RF pins 150 has a proximal end attached to a respective RF contact 146 at or on the surface 122 and a distal end that extends perpendicularly away from the surface 122, through the substrate 160, and into a respective waveguide antenna 180. To span this distance, the RF pins 150 typically have a length of 0.5 centimeters (cm) to 1.0 cm or approximately the same, although lengths may be varied based on substate thickness and coupling hardware of the waveguide antennas 180, for example. The RF contacts 146 are contact pads that may be similar in size, shape, and composition to the contact pads 142, although there is no requirement for the RF contacts 146 to be identical to the contact pads 142. In an example, an RF pin 150 is attached to an RF contact 146 by soldering, such as laser-assisted bonding. Preferably, a higher melting point solder is used for attaching the RF pin 150 to the contact 146 than is used in the solder balls 144. The higher melting point ensures that the device 110 can be soldered to the substrate 160 without the risk of desoldering the RF pin 150. In some arrangements (not shown), an RF pin 150 may be attached to an internal RF contact inside the package 120, such as on the chip 130 itself or on a contact provided on an interposer or fanout structure encapsulated within the package 120. The package 120 may be composed of plastic or ceramic, for example.

The chip 130 typically includes both RF circuitry, i.e., circuitry designed to operate in the tens of gigahertz or higher, and non-RF circuitry, i.e., circuitry designed to operate at lower frequencies. The RF circuitry includes an RF signal node 132 and a corresponding shield node 134 (two of each are shown). The RF signal node 132 is electrically coupled to an RF output and/or an RF input of the chip 130, such as an output or input of an RF power amplifier, sensor, transmission line, splitter, or any other RF input or output terminal, and the shield node 134 is electrically coupled to a local ground, system ground, or to some other stable voltage supply. The RF signal node 132 is electrically coupled to the RF contact 146, and the shield node 134 is electrically coupled to a contact pad 142, e.g., the labeled contact pad 142 shown adjacent to the rightmost RF pin 150 in FIG. 1. In some examples, multiple contact pads 142 surround the RF contact 146, with each such contact pad 142 being electrically coupled to the shield node 134. A contact pad 142 electrically coupled to a shield node 134 may be referred to herein as a “shield contact.” Preferably, the shield contacts 142 for an RF contact 150 surround and are immediately adjacent to the RF contact 150. As used herein, “immediately adjacent” means that there are no interposed contacts. As such, two contacts are immediately adjacent when they are directly next to each other with no other contacts disposed between them.

The package 110 may include any number of RF pins 150. In an example, the chip 130 is a monolithic microwave integrated circuit (MMIC) mounted within the package 120 in a flip-chip arrangement, and the package 120 is a flip chip chip scale package (FCCSP). Embodiments are not limited to these examples, however.

Continuing with reference to FIG. 1, the substrate 160 has a top side (“first side”) 162 attached to the device 110 and a bottom side (“second side”) 164 attached to the waveguide antenna(s) 180. The substrate 160 further includes one or more plated holes 170. Two plated holes 170 are shown, one for each of the two depicted RF pins 150. The RF pins 150 are extended through the plated holes 170 without touching the sides of the plated holes 170.

The interior walls of the plated holes 170 are covered with metal, such as copper, aluminum, gold, or the like, and each plated hole 170 has an upper shield pad 172 and a lower shield pad 174, which are electrically continuous with the metal walls of the respective plated hole 170. The upper surface 162 of the substrate 160 includes at least one substrate contact 156 (e.g., a pad or land) adjacent to and electrically coupled to the shield pad 172 of a respective plated hole 170. Preferably, multiple substrate contacts 156 immediately surround the plated hole 170 and are electrically coupled to the shield pad 172. Such substrate contacts 156 are further electrically coupled to respective shield contacts 142 of the device 110, e.g., through respective solder balls 144.

Each RF pin 150 and associated plated hole 170 through which the RF pin extends define a vertical coaxial structure 162 through the substrate 160, with the RF pin 150 providing a center conductor and the plated hole 170 providing a shield. Also, the geometry of the RF pin 150 and the plated hole 170, along with the material between them, define a characteristic impedance of the coaxial structure 162, which may be maintained consistently over the thickness of the substrate 160. Preferably, the material between the RF pin 150 and the plated hole 170 is air, which provides low dielectric loss at expected operating frequencies. In other words, with the RF pins 150 inserted, an air dielectric is present between the RF pins 150 and the sides of the plated holes 170. Other materials may be used, however, such as low dielectric-constant plastic. Such plastic can also serve to maintain centeredness of the RF pin 150 within the plated hole 170 during assembly. The characteristic impedance of the coaxial structure 162 may be varied by varying the width of the RF pin 150, the diameter of the plated hole 170, and/or the material between the RF pin 150 and the plated hole 170. One should appreciate that RF signal transmission through the coaxial structures 162 is insensitive to the material of which the substrate 160 is composed. For example, the substrate 160 may be composed of standard FR-4 circuit board material without degrading RF performance.

The device 110 may form many other connections with the substrate 160, e.g., for carrying power, ground, signals, etc., which connections are omitted from the figure for the sake of clarity. Also, the substrate 160 is typically much larger than depicted and typically has multiple devices attached to it.

As further shown in FIG. 1, one or more waveguide antennas 180 are coupled to the bottom surface 164 of the substrate 160 opposite the device 110, e.g., using screws, solder, and/or other types of attachment. Each depicted waveguide antenna 180 has conductive walls 182, a rectangular cross section, and a stepped coaxial-to-waveguide transition 184. The stepped transition 184 is a hollow conductive structure inside the waveguide antenna that facilitates impedance matching with a respective coaxial structure 162. In some examples, a waveguide antenna 180 further includes a horn portion 186 for efficiently transmitting and/or receiving RF energy.

Connections between a coaxial structure 162 and the respective waveguide antenna 180 may be made in a variety of ways, the specifics of which are not critical to this disclosure. In one example, the waveguide antenna 180 includes a conductive barrel 188 electrically coupled between the lower shield pad 174 and the stepped transition 184. Preferably, the barrels 188 have the same inner diameter as the plated holes 170. The RF pin 150 is passed through the center of the barrel 188 and into the interior of the stepped transition 184 (e.g., through a clearance hole), thus completing the coaxial-to-waveguide connection. One should appreciate that the arrangement shown is merely an example provided for illustration and is not intended to be limiting.

FIG. 2 is a bottom plan view of the example device 110 of FIG. 1 prior to attachment of the device 110 to the substrate 160 according to one or more embodiments. Here, the terminals of the device 110 are arranged in a grid 210 having rows and columns. In the example shown, each RF pin 150 and associated RF contact 146 is surrounded by multiple shield contacts 142 (shown in cross hatching). The labeled RF pin 150 is disposed in a particular row 220 and in a particular column 230 of the grid 210. Shield contacts 142 are provided in the same row 220 and in immediately adjacent columns (left and right), and in the same column 230 and in immediately adjacent rows (above and below). Additional shield contacts 142 are provided in the four indicated corners. In this manner, coaxial shielding is provided around each RF pin 150. Within the device 110, each RF pin 150 is electrically coupled to a respective RF node 132 (FIG. 1). Also, the shield contacts 142 surrounding each RF pin 150 are coupled to a respective shield node 134. Other terminals 140 are electrically coupled to power, ground, and various signal nodes within the device 110.

In the example shown, each RF pin 150 occupies only a single position of the grid 210. Indeed, the RF pin 150 does not require any more space on the package 120 than do the standard terminals 140. RF connections can thus be made using much less package space than was required by the prior LiP solution.

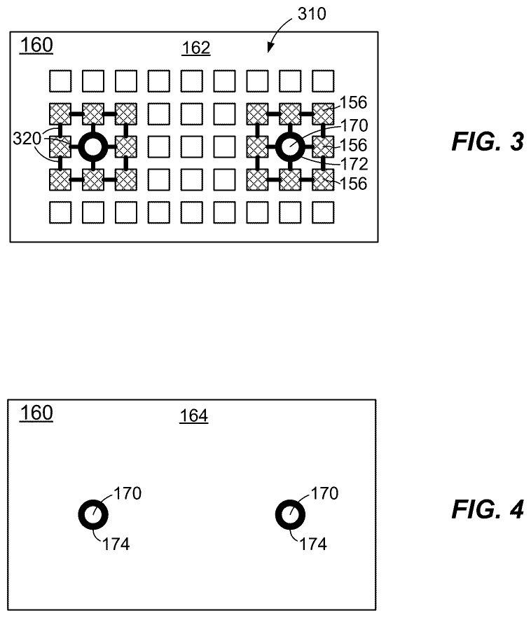

FIG. 3 is a top plan view of the example substrate 160 of FIG. 1 prior to assembly. Multiple substrate contacts 310 (e.g., pads or lands) are provided as a mirror image or substantial mirror image of respective contacts 142 of the device 110, i.e., for enabling the device 110 to be soldered to the substrate 160 via respective solder balls 144. The substrate contacts 310 include the above-mentioned contacts 156 (shown with cross hatching), which connect to shield contacts 142 of the device 110 when the device is soldered to the substrate 160. Also visible in FIG. 3 are plated holes 170 and associated upper shield pads 172. In an example, the substrate contacts 156 surrounding each plated hole 170 are connected together and to the respective upper shield pad 172 via conductive traces 310, thus providing a shield fence around the entry of the plated hole 170. A “trace” as used herein refers to an electrically conductive feature, such as a portion of a patterned conductive layer of a printed circuit board or other substrate. Although a shield fence of component-side pads 156 is preferred for optimal performance, one should appreciate that only a single substrate contact 156 is needed for continuity with a shield contact 142. The other substrate contacts may be omitted in one or more embodiments.

FIG. 4 is a bottom plan view of the example substrate 160 of FIG. 1 prior to assembly. The plated holes 170 are shown along with the associated lower shield pads 174. In an example, the lower shield pads 174 are exposed for electrically connecting with respective barrels 188 of the waveguide antennas 180 when the waveguide antennas 180 are attached to the substrate 160.

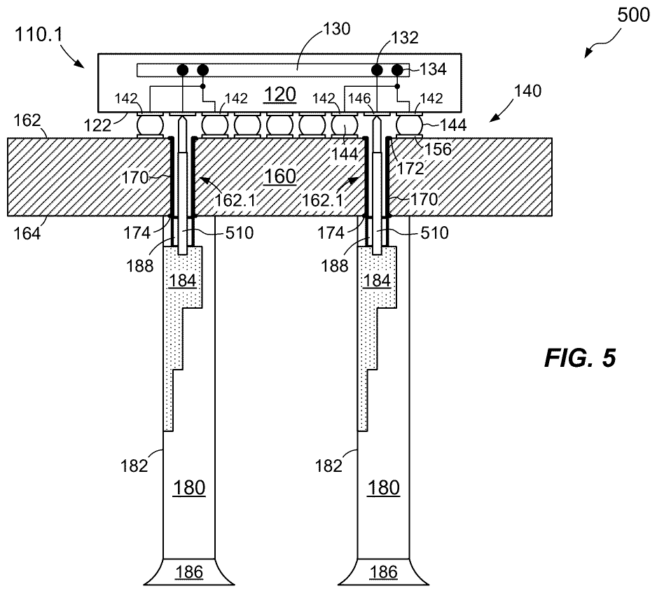

FIG. 5 is a front, cross-sectional view of another circuit assembly 500 according to one or more embodiments. The circuit assembly 500 is similar to the circuit assembly 100 of FIG. 1, with the primary difference being that the RF pins 150 of FIG. 1 are absent from the device 110.1 and instead have been replaced by pins 510 (also called “RF pins”) that extend upwardly from the waveguide antennas 180. In an example, the pins 510 are spring-loaded pogo pins which are held in compression against RF contacts 146 of the device 110.1, rather than being bonded to the device 110.1. It is noted that no solder ball 144 is provided for the RF contact 146. In these embodiments, coaxial structures 162.1 are formed with pins 510 providing the center conductors and plated holes 170 providing the shields. As with the circuit assembly 100, the circuit assembly 500 is also insensitive to the material that composes the substrate, as no substrate material is disposed between the pin 510 and the plated hole 170. Other details of the circuit assembly 500, including those of the device 110.1, substrate 160, and the waveguide antennas 180 are similar or substantially similar to those described above in connection with FIGS. 1-4.

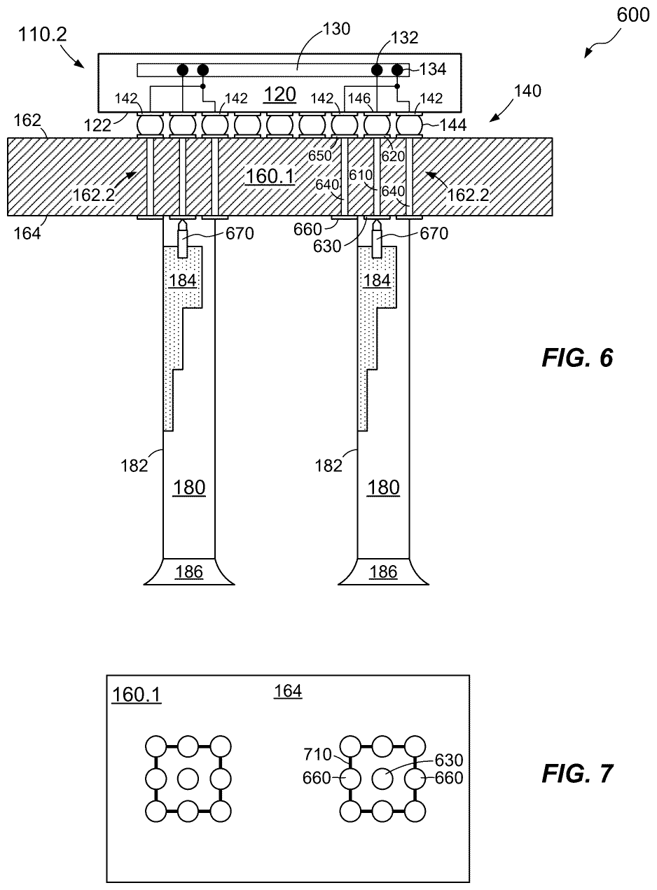

FIG. 6 is a front, cross-sectional view of yet another circuit assembly 600 according to one or more embodiments. In these embodiments, the RF pin 150 has been replaced with a central via 610, i.e., a vertical conductive structure that runs through the substrate (now labeled 160.1) from a substrate contact 620 on the first surface 162 to a substrate contact 630 on the second surface 164. The substrate 160.1 further includes multiple shield vias 640, which also run through the substrate 160.1 from substrate contacts 650 to respective substrate contacts 660 and laterally surround or substantially laterally surround the central via 610. The device, now labeled 110.2, may use conventional terminals such as solder balls 144 on the RF contacts 146. Thus, no special treatment or additional manufacturing activity is needed for accommodating these terminals. Preferably, the central vias 610 and shield vias 640 are solid vias, rather than plated through holes, as plated through holes might draw in solder by capillary action and prevent reliable solder joints from forming between the device 110.2 and the substrate 160.1.

In the circuit assembly 600, coaxial structures 162.2 are formed with central vias 610 providing the center conductors and shield vias 640 providing the shields. In these embodiments, pins 670 (e.g., pogo pins) may be provided between the waveguide antennas 180 and the lands 630. Similar pogo pins (not shown) or other structures may be provided for connecting second lands 660 to the waveguide antennas 180. Unlike the previous examples, where the material of the substrate had no bearing on RF performance, the circuit assembly 600 uses substrate material between each central via 610 and its surrounding shield vias 640. Thus, low dielectric constant substrate materials are preferred in these embodiments. Other details of the circuit assembly 600, including those of the device 110.2, substrate 160.1, and the waveguide antennas 180 are similar or substantially similar to those described in connection with FIGS. 1-4.

FIG. 7 is a bottom plan view of the substrate 160.1 of FIG. 6 according to one or more embodiments. Here, the substrate contact 630 for each central via 630 is surrounded by a total of eight substrate contacts 660 for respective shield vias 640, which all preferably are electrically coupled to a shield node 134 inside the chip 120. Additional connections between the substrate contacts 660 for shield vias 640 may be made using traces 710. The substrate contact 630 for each central via 610 provides a contact point for a pin 670, and the pads 660 for the shield vias 640 provide contact points for shield connections to the waveguide antenna 180, such as pins or other structures.

FIG. 8 is a partially transparent, isometric view of a circuit assembly 800 according to one or more embodiments. The circuit assembly 800 is intended to be representative of the circuit assemblies 100, 500, and 600. The circuit assembly 800 may find useful applications in automotive radar and other RF and microwave technologies. For example, the circuit assembly 800 may be provided as part of a radar sensor used in an automotive radar system.

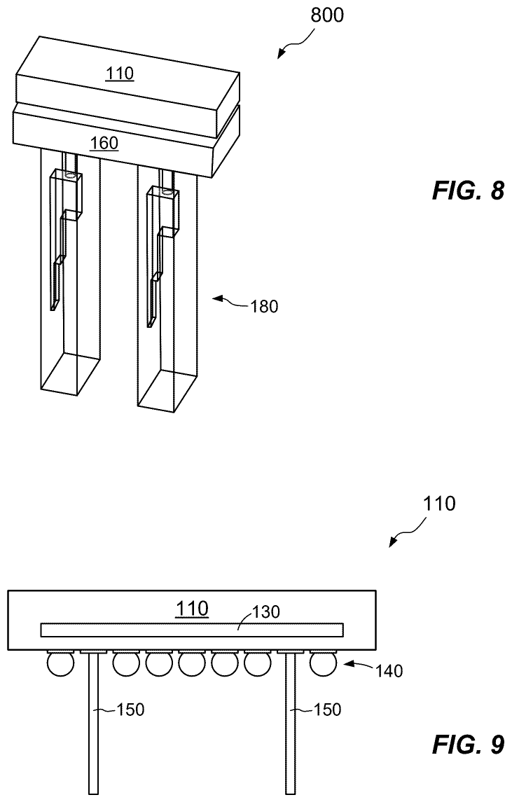

FIG. 9 is an elevated front view of the packaged electronic device 110 of FIGS. 1 and 2, shown separately from the circuit assembly 100. For example, the device 110 may be manufactured as a separate component, which is later incorporated into the circuit assembly 100. According to one or more embodiments, the circuit assembly 100 is made by placing the packaged electronic device against the first side 162 of the substrate 160 with the RF pins 150 extending through the plated holes 170 (FIG. 1) and without touching the plated holes 170. The device 110 may then be soldered to the substrate 160, generally as part of a process that solders other components to the substrate 160. Next, for example, the waveguide antennas 180 are attached to the second side 164 of the substrate 160, e.g., using screws, solder, or other attachments, such that the RF pins 150 and respective plated holes 170 form coaxial-to-waveguide connections 162 with the waveguide antennas.

An improved technique has been described for conveying RF signals between a packaged electronic device (110, 110.1, 110.2) and a waveguide antenna 180. The packaged electronic device contains an integrated circuit 130 configured to transmit and/or receive RF signals. The device 110 is attached (e.g., soldered) to a first side 162 of a substrate 160, such as a printed circuit board, ceramic substrate, or flex board, and the waveguide antenna 180 is attached (e.g., soldered, screwed, or otherwise fastened) to a second side 164 of the substrate 160 opposite the first side 162. The device includes an RF contact 146 and an adjacent shield contact 142. Inside a package 120 of the device, the RF contact 146 and the shield contact 142 are electrically coupled to RF circuitry of the integrated circuit, such as nodes 132 and 134. Outside the package 120, the RF contact 146 is electrically coupled to the waveguide antenna 180 along an inner conductive structure (150, 510, 610) that extends vertically through the substrate 160, and the shield contact 142 is electrically coupled to the waveguide antenna 180 along an outer conductive structure (170, 640) that at least partially surrounds the inner conductive structure. The inner conductive structure and the outer conductive structure form a coaxial vertical structure (162, 162.1, 162.2) which provides a controlled impedance path through the substrate 160, enabling RF signals to propagate between the device and the waveguide antenna without significant losses or reflections.

Advantageously, the improved technique consumes less package space and less substrate space than does the prior LiP solution. Additionally, the improved technique provides comparable insertion loss to the LiP solution. For example, simulation results have shown that insertion loss with the circuit assembly 100 is within about 0.2 dB of that provided by the LiP solution, while insertion loss for the circuit assemblies 500 and 600 are within about 0.9 dB. Thus, the improved technique enables size reductions in RF and microwave devices and assemblies without materially sacrificing performance.

Certain embodiments are directed to a circuit assembly. The circuit assembly includes a packaged electronic device having an RF (radio frequency) contact and a shield contact. The circuit assembly further includes a substrate coupled to the packaged electronic device and at least partially containing an inner conductive structure electrically coupled to the RF contact and an outer conductive structure electrically coupled to the shield contact. The inner conductive structure and the outer conductive structure form a vertical coaxial structure through the substrate. The circuit assembly still further includes a waveguide antenna electrically coupled to the coaxial structure on a side of the substrate opposite the packaged electronic device.

According to one or more further embodiments, the waveguide antenna includes a three-dimensional antenna and a stepped coaxial-to-waveguide transition.

According to one or more further embodiments, the packaged electronic device has a surface at which the RF contact and the shield contact are exposed, and the substrate includes a plated hole vertically aligned with the RF contact and electrically coupled to the shield contact, the plated hole providing the outer conductive structure of the coaxial structure.

According to one or more further embodiments, the inner conductive structure of the coaxial structure includes an RF pin that extends through the plated hole in the substrate without touching the plated hole.

According to one or more further embodiments, the shield contact is one of multiple shield contacts that at least partially surround the RF contact along the surface of the packaged electronic device. The substrate includes one or more substrate contacts aligned with the multiple shield contacts and electrically coupled to the plated hole, and the multiple shield contacts are electrically coupled to the plated hole through the one or more substrate contacts.

According to one or more further embodiments, the package includes a type of package selected from a group consisting of a ball grid array package and a land grid array package, and the multiple shield contacts include conductive pads.

According to one or more further embodiments, the RF contact includes a contact pad, and the waveguide antenna includes an RF pin that extends from the waveguide antenna up through the plated hole in the substrate without touching the plated hole and makes contact with the contact pad, the RF pin forming the inner conductive structure of the coaxial structure.

According to one or more further embodiments, the packaged electronic device further includes an RF pin extending from the surface through the plated hole in the substrate without touching the plated hole, the RF pin forming the inner conductive structure of the coaxial structure.

According to one or more further embodiments, the pin is a spring-loaded pogo pin.

According to one or more further embodiments, the shield contact is one of multiple shield contacts that at least partially surround the RF contact along the surface of the packaged electronic device, and the multiple shield contacts are electrically coupled to the plated hole.

According to one or more further embodiments, the multiple shield contacts include respective contact pads identical to the contact pad of the RF contact, and the contact pads of the shield contacts but not the RF contact pad are connected to the substrate through one or more substrate contacts that are aligned with the multiple shield contacts and electrically coupled to the plated hole.

According to one or more further embodiments, the contact pads of the shield contacts are connected to the one or more substrate contacts with solder balls, and the contact pad of the RF contact has no solder ball attached thereto.

According to one or more further embodiments, the substrate includes a central via that is vertically aligned with the RF contact and extends from a first side of the substrate to a second side of the substrate, and wherein the central via is connected to the RF contact to form the inner conductive structure of the coaxial structure.

According to one or more embodiments, the substrate includes multiple shield vias that at least partially surround the central via to form the outer conductive structure of the coaxial structure. The shield vias are electrically coupled to the shield contact.

Additional embodiments are directed to a packaged electronic device. The packaged electronic device includes an integrated circuit that includes an RF signal node and a shield node, a package that contains the integrated circuit, the package having a surface, a plurality of electrical contacts at the surface, and an RF pin coupled to the surface. The RF pin is electrically coupled to the RF signal node and extends farther outward from the surface than the plurality of electrical contacts. The plurality of electrical contacts includes at least one contact electrically coupled to the shield node and disposed immediately adjacent to the RF pin.

According to one or more further embodiments, the plurality of electrical contacts includes at least one additional contact electrically coupled to the shield node and disposed immediately adjacent to the RF pin.

According to one or more further embodiments, the plurality of electrical contacts includes respective contact pads.

According to one or more further embodiments, the packaged electronic device further includes at least one additional RF pin electrically coupled to at least one additional RF signal node, each additional RF pin extending farther from the surface than the plurality of electrical contacts.

According to one or more further embodiments, the RF pin, or each RF pin, is soldered to the package using laser-assisted bonding.

According to one or more further embodiments, the plurality of electrical contacts is arranged in a grid having rows and columns. The RF pin is disposed at an intersection of a particular row of the grid and a particular column of the grid, and the RF pin is adjacent to (i) first and second electrical contacts of the plurality of electrical contacts in the particular row of the grid and in immediately adjacent columns of the grid, and (ii) third and fourth electrical contacts of the plurality of electrical contacts in the particular column of the grid and in immediately adjacent rows of the grid.

Having described certain embodiments, numerous alternative embodiments or variations can be made. Further, although features have been shown and described with reference to particular embodiments hereof, such features may be included and hereby are included in any of the disclosed embodiments and their variants. Thus, it is understood that features disclosed in connection with any embodiment are included in any other embodiment.

As used throughout this document, the words “comprising,” “including,” “containing,” and “having” are intended to set forth certain items, steps, elements, or aspects of something in an open-ended fashion. Also, as used herein and unless a specific statement is made to the contrary, the word “set” means one or more of something. This is the case regardless of whether the phrase “set of” is followed by a singular or plural object and regardless of whether it is conjugated with a singular or plural verb. Also, a “set of” elements can describe fewer than all elements present. Thus, there may be additional elements of the same kind that are not part of the set. Further, ordinal expressions, such as “first,” “second,” “third,” and so on, may be used as adjectives herein for identification purposes. Unless specifically indicated, these ordinal expressions are not intended to imply any ordering or sequence. Thus, for example, a “second” event may take place before or after a “first event,” or even if no first event ever occurs. In addition, an identification herein of a particular element, feature, or act as being a “first” such element, feature, or act should not be construed as requiring that there must also be a “second” or other such element, feature or act. Rather, the “first” item may be the only one. Also, and unless specifically stated to the contrary, “based on” is intended to be nonexclusive. Thus, “based on” should be interpreted as meaning “based at least in part on” unless specifically indicated otherwise. Further, although the term “user” as used herein may refer to a human being, the term is also intended to cover non-human entities, such as robots, bots, and other computer-implemented programs and technologies. Although certain embodiments are disclosed herein, it is understood that these are provided by way of example only and should not be construed as limiting.

Also, the foregoing description refers to elements or nodes or features being “connected” or “coupled” together. As used herein, unless expressly stated otherwise, “connected” means that one element is directly joined to (or directly communicates with) another element, and not necessarily mechanically. Likewise, unless expressly stated otherwise, “coupled” means that one element is directly or indirectly joined to (or directly or indirectly communicates with, electrically or otherwise) another element, and not necessarily mechanically. Thus, although the schematics and component features shown in the figures depict one exemplary arrangement of elements, additional intervening elements, devices, features, or components may be present in one or more other embodiments of the depicted subject matter.

Those skilled in the art will therefore understand that various changes in form and detail may be made to the embodiments disclosed herein without departing from the scope of the following claims.

1-14. (canceled)

15. A circuit assembly, comprising:
a packaged electronic device having a radio frequency (RF) contact and a shield contact;
a substrate coupled to the packaged electronic device and at least partially containing an inner conductive structure electrically coupled to the RF contact and an outer conductive structure electrically coupled to the shield contact, the inner conductive structure and the outer conductive structure forming a vertical coaxial structure through the substrate; and
a waveguide antenna electrically coupled to the coaxial structure on a side of the substrate opposite the packaged electronic device.

16. The circuit assembly of claim 15, wherein the waveguide antenna includes a three-dimensional antenna and a stepped coaxial-to-waveguide transition.

17. The circuit assembly of claim 15, wherein the packaged electronic device has a surface at which the RF contact and the shield contact are exposed, and wherein the substrate includes a plated hole vertically aligned with the RF contact and electrically coupled to the shield contact, the plated hole providing the outer conductive structure of the coaxial structure.

18. The circuit assembly of claim 17, wherein the inner conductive structure of the coaxial structure includes an RF pin that extends through the plated hole in the substrate without touching the plated hole.

19. The circuit assembly of claim 18, wherein the shield contact is one of multiple shield contacts that at least partially surround the RF contact along the surface of the packaged electronic device, wherein the substrate includes one or more substrate contacts aligned with the multiple shield contacts and electrically coupled to the plated hole, and wherein the multiple shield contacts are electrically coupled to the plated hole through the one or more substrate contacts.

20. The circuit assembly of claim 19, wherein the package includes a type of package selected from a group consisting of a ball grid array package and a land grid array package, and wherein the multiple shield contacts include conductive pads.

21. The circuit assembly of claim 17, wherein the RF contact includes a contact pad, and wherein the waveguide antenna includes an RF pin that extends from the waveguide antenna up through the plated hole in the substrate without touching the plated hole and makes contact with the contact pad, the RF pin forming the inner conductive structure of the coaxial structure.

22. The circuit assembly of claim 17, wherein the packaged electronic device further includes an RF pin extending from the surface through the plated hole in the substrate without touching the plated hole, the RF pin forming the inner conductive structure of the coaxial structure.

23. The circuit assembly of claim 21, wherein the pin is a spring-loaded pogo pin.

24. The circuit assembly of claim 17, wherein the shield contact is one of multiple shield contacts that at least partially surround the RF contact along the surface of the packaged electronic device, and wherein the multiple shield contacts are electrically coupled to the plated hole.

25. The circuit assembly of claim 24, wherein the multiple shield contacts include respective contact pads identical to the contact pad of the RF contact, and wherein the contact pads of the shield contacts but not the RF contact pad are connected to the substrate through one or more substrate contacts that are aligned with the multiple shield contacts and electrically coupled to the plated hole.

26. The circuit assembly of claim 24, wherein the contact pads of the shield contacts are connected to the one or more substrate contacts with solder balls, and wherein the contact pad of the RF contact has no solder ball attached thereto.

27. The circuit assembly of claim 15, wherein the substrate includes a central via that is vertically aligned with the RF contact and extends from a first side of the substrate to a second side of the substrate, and wherein the central via is connected to the RF contact to form the inner conductive structure of the coaxial structure.

28. The circuit assembly of claim 27, wherein the substrate includes multiple shield vias that at least partially surround the central via to form the outer conductive structure of the coaxial structure, wherein the shield vias are electrically coupled to the shield contact.

29. A packaged electronic device, comprising:
an integrated circuit that includes an RF signal node and a shield node;
a package that contains the integrated circuit, the package having a surface;
a plurality of electrical contacts at the surface; and
an RF pin coupled to the surface, wherein the RF pin is electrically coupled to the RF signal node and extends farther outward from the surface than the plurality of electrical contacts, and
wherein the plurality of electrical contacts include at least one contact electrically coupled to the shield node and disposed immediately adjacent to the RF pin.

30. The packaged electronic device of claim 29, wherein the plurality of electrical contacts includes at least one additional contact electrically coupled to the shield node and disposed immediately adjacent to the RF pin.

31. The packaged electronic device of claim 30, wherein the plurality of electrical contacts includes respective contact pads.

32. The packaged electronic device of claim 29, further comprising at least one additional RF pin electrically coupled to at least one additional RF signal node, each additional RF pin extending farther from the surface than the plurality of electrical contacts.

33. The packaged electronic device of claim 29, wherein the RF pin is attached to the package using laser-assisted bonding.

34. The packaged electronic device of claim 29, wherein the plurality of electrical contacts is arranged in a grid having rows and columns, wherein the RF pin is disposed at an intersection of a particular row of the grid and a particular column of the grid, and wherein the RF pin is adjacent to (i) first and second electrical contacts of the plurality of electrical contacts in the particular row of the grid and in immediately adjacent columns of the grid, and (ii) third and fourth electrical contacts of the plurality of electrical contacts in the particular column of the grid and in immediately adjacent rows of the grid.
